(19) United States
(12) Patent Application Publication
(10) Pub. No.: US 2019/0146565 A1
(43) Pub. Date: May 16, 2019

(54) DATA CENTER FUEL CELLS

(71) Applicant: Hewlett Packard Enterprise Development LP, Houston, TX (US)

(72) Inventors: Tahir Cader, Liberty Lake, WA (US); Javier Izquierdo, Houston, TX (US)

(21) Appl. No.: 16/189,340

(22) Filed: Nov. 13, 2018

Related U.S. Application Data
(60) Provisional application No. 62/585,377, filed on Nov. 13, 2017.

(51) Int. Cl. G06F 1/30; H02J 9/06; H02J 1/00; H05K 7/14; H01M 8/04537; H01M 8/04664

(52) U.S. Cl. CPC G06F 1/305; H02J 9/062; H02J 1/00; H02J 2001/004; H01M 8/04567; H01M 8/04686; H05K 7/1492

(57) ABSTRACT

Example implementations relate to data center fuel cells. In some examples, a controller for data center fuel cells can include instructions to: determine when a load for a data center that exceeds a power threshold, determine a first quantity of power to be provided by a first power source and a second quantity of power to be provided by a second power source such that a sum of the first quantity of power and the second quantity of power is equal to or exceeds the power threshold for the data center, provide the first quantity of power utilizing the first power source, wherein the first quantity of power is less than the power threshold, and provide the second quantity of power utilizing the second power source.

### BACKGROUND

A data center can include a plurality of server chassis that each include a plurality of computing devices such as servers. In some examples, the data center can receive electrical power from an electrical grid. An electrical grid can include a network that delivers electricity from producers to consumers. The producers can be power generators that produce electricity that is distributed by a plurality of power lines to consumers. In some examples, the electrical grid can fail and result in a power outage for a particular area.

### BRIEF DESCRIPTION OF THE DRAWINGS

FIG. 1 illustrates an example system for data center fuel cells consistent with the present disclosure.

FIG. 2 illustrates an example system for data center fuel cells consistent with the present disclosure.

FIG. 3 illustrates an example system for data center fuel cells consistent with the present disclosure.

FIG. 4 illustrates an example system for data center fuel cells consistent with the present disclosure.

FIG. 5 illustrates an example controller for data center fuel cells consistent with the present disclosure.

FIG. 6 illustrates an example computing device for data center fuel cells consistent with the present disclosure.

FIG. 7 illustrates an example system for data center fuel cells consistent with the present disclosure.

### DETAILED DESCRIPTION

Example implementations relate to data center fuel cells. In some examples, a controller for data center fuel cells can include instructions to: determine when a load for a data center exceeds a power threshold, determine a first quantity of power to be provided by a first power source and a second quantity of power to be provided by a second power source such that a sum of the first quantity of power and the second quantity of power is equal to or exceeds the power threshold for the data center, provide the first quantity of power utilizing the first power source, wherein the first quantity of power is less than the power threshold, and provide the second quantity of power utilizing the second power source. In some examples, the data center fuel cell systems can be utilized to provide backup power to computing devices of the data center when there is a grid failure (e.g., power outage of an electrical grid, etc.). In other examples, the data center fuel cell system can be utilized to provide a first percentage of electrical energy from a first source and a second percentage of electrical energy from a second source.

Previous systems can utilize a generator (e.g., diesel generator, etc.) with a plurality of uninterruptible power supplies (UPSs) to provide backup power to a data center when an electrical grid fails. For example, a data center can be coupled to a number of UPS devices. In this example, the UPS devices can be coupled to an electrical grid and a diesel generator. In this example, the UPS devices can provide temporary electrical power to the data center when the UPS devices detect that the electrical grid has failed. In addition, the power can be switched from the electrical grid to the diesel generator when the electrical grid fails for an extended period of time.

These previous systems can be relatively expensive to maintain (e.g., maintenance of diesel generators, maintenance of UPS devices, etc.) compared to the data center fuel cell systems described herein. In addition, the previous systems can generate more pollution than the data center fuel cell systems described herein. Furthermore, the previous systems may not be able to shave power usage from the electrical grid and utilize a smaller percentage of power from the electrical grid without incurring additional cost of utilizing a diesel generator. In contrast, the data center fuel cell systems described herein can provide backup electrical power to the data center when a failure occurs on the electrical grid without utilizing a centralized device or utilizing diesel generators. In addition, the data center fuel cell systems can be utilized to provide continuous power to the data center when electrical energy producers are providing incentives for decreasing electrical energy utilized from the electrical grid. By eliminating the use of centralized devices and/or diesel generators, the systems described herein can provide a relatively lower maintenance cost and a relatively cleaner solution to providing backup power and continuous power to a data center.

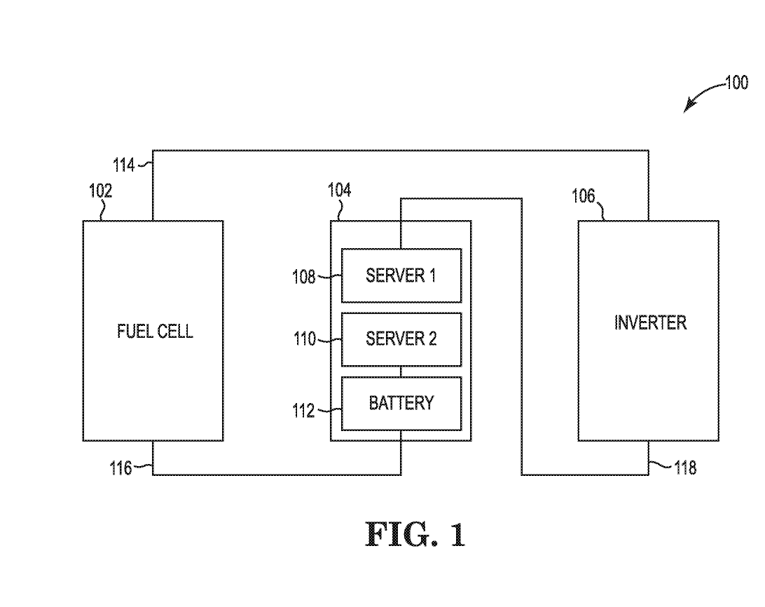

FIG. 1 illustrates an example system 100 for data center fuel cells consistent with the present disclosure. The system 100 can be utilized to provide backup and/or continuous power to a data center 104. For example, the system 100 can be utilized to provide electrical energy to the data center 104 when a failure occurs on an electrical grid. In another example, the system 100 can be utilized to provide a first portion of the electrical energy provided to the data center 104 while a second portion of the electrical energy is provided to the data center 104 by the electrical grid. In addition, the system 100 can provide electrical energy to the data center 104 without utilizing a centralized device.

In some examples, the system 100 can include a fuel cell 102. As used herein, a fuel cell 102 can, for example, be a device that generates electricity from a fuel source (e.g., hydrogen, etc.) by converting chemical energy from the fuel source to electrical energy. For example, the fuel cell 102 can be provided hydrogen as a fuel source and the fuel cell 102 can generate electrical energy through an electrochemical reaction of the hydrogen with an oxidizing agent. In some examples, the fuel cell 102 can generate direct current (DC) electrical energy. In these examples, the fuel cell 102 can be utilized to provide electrical power to a number of computing devices (e.g., server 108, server 110, etc.) and/or other components of a data center 104. In some examples, the ramp up time (e.g., time it takes for a device to be utilized by a system, etc.) for the fuel cell 102 can be relatively shorter than a generator (e.g., diesel generator, etc.). Thus, the fuel cell 102 in combination with a battery coupled to the fuel cell 102 can be utilized to power the number of computing devices during a time when the electrical grid is not working properly, during a time of load shedding, and/or during other times when the power of the data center 104 exceeds a threshold. In some examples, the battery 112 can be a plurality of batteries. For example, a plurality of batteries (e.g., battery 112) can be coupled to the fuel cell 102 to be charged by the fuel cell 102. In some examples, when a load of the data center 104 exceeds a quantity of power provided by the fuel cell and/or the grid, the battery 112 can be utilized to provide power to the data center 104 or a portion of the data center 104 for a relatively short period of time. That is, the battery 112 can be utilized to help respond to rapid spikes in the load of the data center 104.

In some examples, the system 100 can include a data center 104. As used herein, a data center 104 can, for example, include a facility to house computing devices and associated components. For example, a data center 104 can include a plurality of server chassis that can include a plurality of computing devices coupled to each of the plurality of server chassis. In this example, the plurality of server chassis can include computing devices that are coupled to an alternating current (AC) power source and computing devices that are coupled to a direct current (DC) power source. In some examples, the plurality of server chassis and the plurality of computing devices can receive electrical energy from an electrical grid. In these examples, a failure of the electrical grid can result in a power failure of the data center 104. In previous systems, a generator and the electrical grid can be coupled to the uninterruptible power supply (UPS) to transition power from the electrical grid to the generator such that data is not lost during the transition.

In some examples, the data center 104 can include a plurality of computing devices (e.g., server 108, server 110, etc.). In some examples, the data center 104 can include a plurality of server chassis that each include a plurality of computing devices (e.g., server 108, server 110, etc.). As described herein, a portion of the computing devices of the data center 104 can be set up to receive AC power and a different portion of the computing devices of the data center 104 can be set up to receive DC power. For example, server 108 can be set up to receive AC power and the server 110 can be set up to receive DC power.

In some examples, the data center 104 can include a battery 112. In some examples, the battery 112 can be a battery for a particular server chassis. For example, the battery 112 can be coupled to a server chassis and/or coupled to a plurality of servers within the server chassis. In some examples, the battery 112 can provide DC power to a plurality of servers and/or other components. For example, the battery 112 can be coupled to server 110. In this example, the server 110 can be set up to receive DC power. In some examples, the battery 112 can be coupled to the fuel cell 102 via connection 116 such that the fuel cell 102 can store electrical energy in the battery 112. For example, the fuel cell 102 can be utilized to generate DC power and the generated DC power of the fuel cell 102 can be utilized to charge the battery 112. In some examples, the fuel cell 102 can be utilized to directly provide power to the server 108 and/or server 110. In some examples, the fuel cell 102 can be utilized to charge the battery 112 while also providing power to the server 108 and/or server 110 in parallel. In another example, the fuel cell 102 can be utilized to charge the battery 112 and the battery 112 can be utilized to provide power to the server 108 and/or server 110.

In some examples, the system 100 can include an inverter 106. In some examples, the inverter 106 can be a DC to AC inverter. For example, the inverter 106 can receive DC power from the fuel cell 102 via connection 114 and convert the DC power to AC power. In this example, the AC power can be provided to server 108 via connection 118. In this example, the server 108 can be set up to receive AC power and thus the system 100 can include the DC to AC inverter 106 to convert the DC power generated by the fuel cell 102 to a usable AC power for the server 108.

The system 100 can include a plurality of devices that can be utilized to provide backup power and/or continuous power to the data center 104. Even though some of the devices are shown within the data center 104 and other devices are shown outside the data center 104, the location of the devices can be altered such that external devices can be positioned within the data center 104 and internal devices can be positioned outside the data center 104. The system 100 can be utilized to provide backup power when an electrical grid fails or provide continuous power to lower a usage of the electrical grid. In some examples, the system 100 can provide a relatively cleaner alternative to using diesel generators as well as provide a more effective way to provide continuous power to lower usage of the electrical grid.

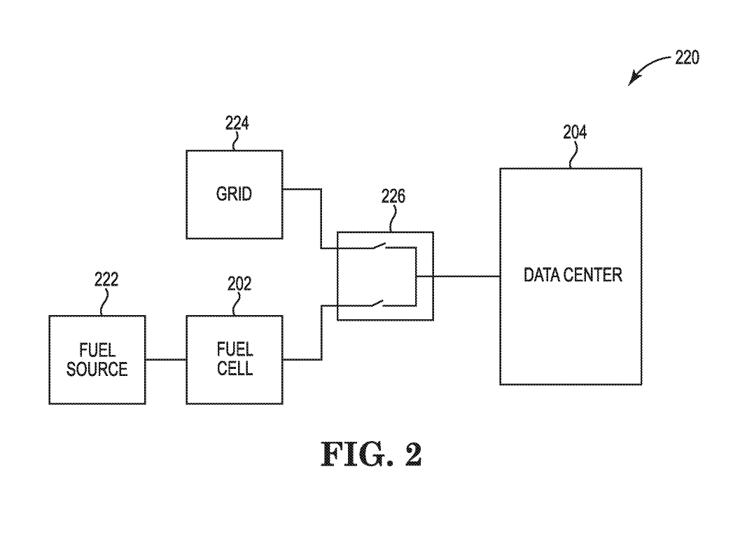

FIG. 2 illustrates an example system 220 for data center fuel cells consistent with the present disclosure. In some examples, the system 220 can be utilized to provide backup power and/or continuous power to a data center 204. The system 220 can include similar elements as system 100. For example, the data center 204 can include the same or similar elements as the data center 104 as referenced in FIG. 1.

In some examples, the system 220 can include a data center 204. The data center 204 can include a plurality of computing devices such as servers and other electrical components to support the servers (e.g., networking devices, cooling devices, etc.). In some examples, the data center 204 can be coupled to a switching mechanism 226 (e.g., automatic transfer switch (ATS), switching circuitry, etc.). As used herein, a switching mechanism 226 can, for example, include an electrical switch that can switch a load (e.g., data center 204, etc.) between a plurality of sources (e.g., electrical grid 224, fuel cell 202, etc.).

In some examples, the switching mechanism 226 can detect a voltage drop from the electrical grid 224 and switch the source from the electrical grid 224 to the fuel cell 202 in response to the voltage drop or a determined failure of the electrical grid 224. In some examples, the switching mechanism 226 can be utilized to allow a first portion of electrical energy to be provided by a first source and allow a second portion of electrical energy to be provided by a second source. For example, the switching mechanism 226 can allow the electrical grid 224 to provide a first percentage of electrical energy to the data center 204 and allow the fuel cell 202 to provide a second percentage of electrical energy to the data center 204. In this example, the fuel cell 202 can be utilized to provide continuous power to the data center 204 and lower the quantity of electrical energy extracted from the electrical grid 224.

In some examples, an energy provider utilizing the electrical grid 224 can make a request that the data center 204 utilize 25 percent less electrical energy from the electrical grid 224 for a particular period of time. In these examples, the switching mechanism 226 can utilize the electrical grid 224 for 75 percent of the electrical energy provided to the data center 204 and utilize the fuel cell 202 for 25 percent of the electrical energy provided to the data center 204. In this way, the data center 204 can accommodate the request by the energy provider while not sacrificing the total electrical energy utilized by the data center 204. In addition, the data center 204 can accommodate the request by the energy provider without increased cost of a diesel generator or increased pollution of a diesel generator.

In some examples, an organization utilizing computing resources of the data center 204 can have predictable spikes in computing resource demand (e.g., pre-Christmas shopping online, time periods when online auctions end, etc.). In these examples, the switching mechanism 226 can utilize additional electrical energy from the fuel cell 202 during the predicted spikes in computing resource demand.

In some examples, the fuel cell 202 can be coupled to a fuel source 222. As used herein, a fuel source 222 can, for example, include a source of fuel to be provided to the fuel cell 202. For example, the fuel source 222 can include a natural gas reformer that can receive natural gas and extract hydrogen. In this example, the extracted hydrogen can be provided to the fuel cell 202. In another example, the fuel source 222 can be an electrolysis device (e.g., electrolyzer, etc.) that can use a renewable energy source (e.g., solar power, wind power, water power, etc.) to extract hydrogen from water molecules. In this example, the extracted hydrogen can be provided to the fuel cell 202.

The system 220 can include a plurality of devices or elements that can be utilized to provide backup power and/or continuous power to the data center 204. Even though some of the devices are shown within the data center 204 and other devices are shown outside the data center 204, the location of the devices can be altered such that external devices can be positioned within the data center 204 and internal devices can be positioned outside the data center 204. The system 220 can be utilized to provide backup power when an electrical grid 224 fails or provide continuous power to lower a usage of the electrical grid 224. In some examples, the system 220 can provide a relatively cleaner alternative to using diesel generators as well as provide a more effective way to provide continuous power to lower usage of the electrical grid 224.

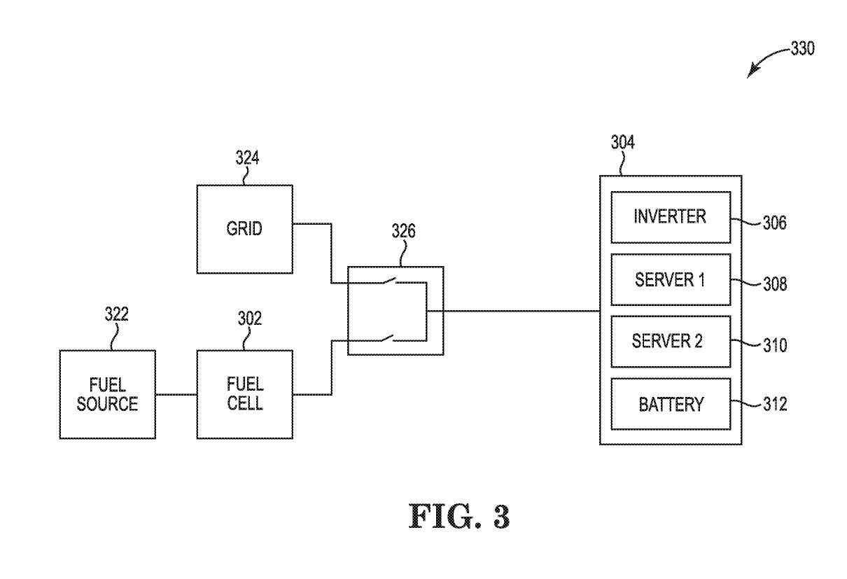

FIG. 3 illustrates an example system 330 for data center fuel cells consistent with the present disclosure. In some examples, the system 330 can be utilized to provide backup power and/or continuous power to a data center 304. The system 330 can include similar elements as system 100 as referenced in FIG. 1 and/or system 220 as referenced in FIG. 2. For example, the data center 304 can include the same or similar elements as the data center 104 as referenced in FIG. 1.

In some examples, the system 330 can include a data center 304. The data center 304 can include a plurality of computing devices such as servers 308, 310 and other electrical components to support the servers (e.g., networking devices, cooling devices, etc.). In some examples, the data center 304 can be coupled to a switching mechanism 326 (e.g., automatic transfer switch (ATS), switching circuitry, etc.). As used herein, a switching mechanism 326 can, for example, include an electrical switch that can switch a load (e.g., data center 304, etc.) between a plurality of sources (e.g., electrical grid 324, fuel cell 302, etc.).

In some examples, the switching mechanism 326 can detect a voltage drop from the electrical grid 324 and switch the source from the electrical grid 324 to the fuel cell 302 in response to the voltage drop or a determined failure of the electrical grid 324. In some examples, the switching mechanism 326 can be utilized to allow a first portion of electrical energy to be provided by a first source and allow a second portion of electrical energy to be provided by a second source. For example, the switching mechanism 326 can allow the electrical grid 324 to provide a first percentage of electrical energy to the data center 304 and allow the fuel cell 302 to provide a second percentage of electrical energy to the data center 304. In this example, the fuel cell 302 can be utilized to provide continuous power to the data center 304 and lower the quantity of electrical energy extracted from the electrical grid 324.

In some examples, the fuel cell 302 can be coupled to a fuel source 322. As used herein, a fuel source 322 can, for example, include a source of fuel to be provided to the fuel cell. For example, the fuel source 322 can include a natural gas reformer that can receive natural gas and extract hydrogen. In this example, the extracted hydrogen can be provided to the fuel cell 302. In another example, the fuel source 322 can be an electrolysis device (e.g., electrolyzer, etc.) that can use a renewable energy source (e.g., solar power, wind power, water power, etc.) to extract hydrogen from water molecules. In this example, the extracted hydrogen can be proved to the fuel cell 302.

In some examples, the system 330 can include a data center 304. As used herein, a data center 304 can, for example, include a facility to house computing devices and associated components. For example, a data center 304 can include a plurality of server chassis that can include a plurality of computing devices coupled to each of the plurality of server chassis. In this example, the plurality of server chassis can include computing devices that are coupled to an alternating current (AC) power source and computing devices that are coupled to a direct current (DC) power source. In some examples, the plurality of server chassis and the plurality of computing devices can receive electrical energy from an electrical grid. In these examples, a failure of the electrical grid can result in a power failure of the data center 304. In previous systems, a generator and an uninterruptible power supply (UPS) could be utilized to transition power from the electrical grid to the generator such that data is not lost during the transition.

In some examples, the data center 304 can include a plurality of computing devices (e.g., server 308, server 310, etc.). In some examples, the data center 304 can include a plurality of server chassis that each include a plurality of computing devices (e.g., server 308, server 310, etc.). As described herein, a portion of the computing devices of the data center 304 can be set up to receive AC power and a different portion of the computing devices of the data center 304 can be set up to receive DC power. For example, server 308 can be set up to receive AC power and the server 310 can be set up to receive DC power.

In some examples, the data center 304 can include a battery 312. In some examples, the battery 312 can be a battery for a particular server chassis. For example, the battery 312 can be coupled to a server chassis and/or coupled to a plurality of servers within the server chassis. In some examples, the battery 312 can provide DC power to a plurality of servers and/or other components. For example, the battery 312 can be coupled to server 310. In this example, the server 310 can be set up to receive DC power. In some examples, the battery 312 can be coupled to the fuel cell 302 such that the fuel cell 302 can store electrical energy in the battery 312. For example, the fuel cell 302 can be utilized to generate DC power and the generated DC power of the fuel cell 302 can be utilized to charge the battery 312. In some examples, the battery 312 can be a plurality of batteries. For example, a plurality of batteries (e.g., battery 312) can be coupled to the fuel cell 302 to provide electrical power to an input of the switching mechanism 326. In some examples, the fuel cell 302 can be utilized to directly provide power to the server 308 and/or server 310. In some examples, the fuel cell 302 can be utilized to charge the battery 312 while also providing power to the server 308 and/or server 310 in parallel. In another example, the fuel cell 302 can be utilized to charge the battery 312 and the battery 312 can be utilized to provide power to the server 308 and/or server 310.

In some examples, the data center 304 can include an inverter 306. In some examples, the inverter 306 can be a DC to AC inverter. For example, the inverter 306 can receive DC power from the fuel cell 302 and convert the DC power to AC power. In this example, the AC power can be provided to server 308. In this example, the server 308 can be set up to receive AC power and thus the system 330 can include the DC to AC inverter 306 to convert the DC power generated by the fuel cell 302 to a usable AC power for the server 308.

The system 330 can include a plurality of devices or elements that can be utilized to provide backup power and/or continuous power to the data center 304. Even though some of the devices are shown within the data center 304 and other devices are shown outside the data center 304, the location of the devices can be altered such that external devices can be positioned within the data center 304 and internal devices can be positioned outside the data center 304. The system 330 can be utilized to provide backup power when an electrical grid 324 fails or provide continuous power to lower a usage of the electrical grid 324. In some examples, the system 330 can provide a relatively cleaner alternative to using diesel generators as well as provide a more effective way to provide continuous power to lower usage of the electrical grid 324.

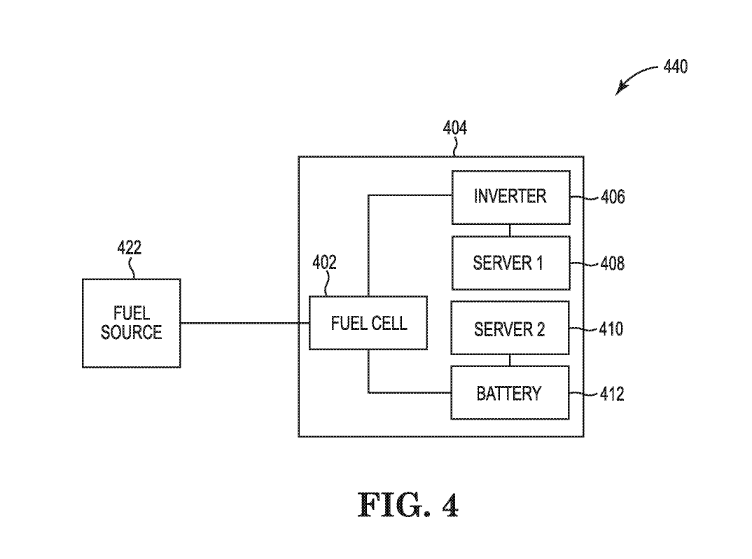

FIG. 4 illustrates an example system 440 for data center fuel cells consistent with the present disclosure. In some examples, the system 440 can be utilized to provide backup power and/or continuous power to a data center 404. The system 440 can include similar elements as system 100 as referenced in FIG. 1, system 220 as referenced in FIG. 2, and/or system 330 as referenced in FIG. 3. For example, the data center 404 can include the same or similar elements as the data center 104 as referenced in FIG. 1.

In some examples, the system 440 can include a data center 404. The data center 404 can include a plurality of computing devices such as servers 408, 410 and other electrical components to support the servers (e.g., networking devices, cooling devices, etc.). In some examples, the data center 404 can include a fuel cell 402. As used herein, a fuel cell 402 can, for example, be a device that generates electricity from a fuel source 422 (e.g., hydrogen, etc.) by converting chemical energy from the fuel source 422 to electrical energy. For example, the fuel cell 402 can be provided hydrogen as a fuel source 422 and the fuel cell 402 can generate electrical energy through an electrochemical reaction of the hydrogen with an oxidizing agent. In some examples, the fuel cell 402 can generate direct current (DC) electrical energy. In these examples, the fuel cell 402 can be utilized to directly provide power to the server 408 and/or server 410. In some examples, the fuel cell 402 can be utilized to charge the battery 412 while also providing power to the server 408 and/or server 410 in parallel. In another example, the fuel cell 402 can be utilized to charge the battery 412 and the battery 412 can be utilized to provide power to the server 408 and/or server 410.

In some examples, the fuel cell 402 can be coupled to a fuel source 422. As used herein, a fuel source 422 can, for example, include a source of fuel to be provided to the fuel cell 402. For example, the fuel source 422 can include a natural gas reformer that can receive natural gas and extract hydrogen from the natural gas. In this example, the extracted hydrogen can be provided to the fuel cell 402. In another example, the fuel source 422 can be an electrolysis device (e.g., electrolyzer, etc.) that can use a renewable energy source (e.g., solar power, wind power, water power, etc.) to extract hydrogen from water molecules. In this example, the extracted hydrogen can be proved to the fuel cell 402.

In some examples, the data center 404 can include a battery 412. In some examples, the battery 412 can be a battery for a particular server chassis. For example, the battery 412 can be coupled to a server chassis and/or coupled to a plurality of servers within the server chassis. In some examples, the battery 412 can provide DC power to a plurality of servers and/or other components. For example, the battery 412 can be coupled to server 410. In this example, the server 410 can be set up to receive DC power. In some examples, the battery 412 can be coupled to the fuel cell 402 such that the fuel cell 402 can store electrical energy in the battery 412. For example, the fuel cell 402 can be utilized to generate DC power and the generated DC power of the fuel cell 402 can be utilized to charge the battery 412.

In some examples, the data center 404 can include an inverter 406. In some examples, the inverter 406 can be a DC to AC inverter. For example, the inverter 406 can receive DC power from the fuel cell 402 and convert the DC power to AC power. In some examples, the inverter 406 can be coupled to a particular server chassis that includes a server 408 that is set up to receive AC power. In these examples, the inverter 406 can be coupled to the same server chassis as server 408 and AC power can be provided to server 408 via the inverter 406. In this example, the server 408 can be set up to receive AC power and thus the data center 404 can include the DC to AC inverter 406 to convert the DC power generated by the fuel cell 402 to a usable AC power for the server 408.

The system 440 can include a plurality of devices or elements that can be utilized to provide backup power and/or continuous power to the data center 404. Even though some of the devices are shown within the data center 404 and other devices are shown outside the data center 404, the location of the devices can be altered such that external devices can be positioned within the data center 404 and internal devices can be positioned outside the data center 404. The system 440 can be utilized to provide backup power when an electrical grid 424 fails or provide continuous power to lower a usage of the electrical grid 424. In some examples, the system 440 can provide a relatively cleaner alternative to using diesel generators as well as provide a more effective way to provide continuous power to lower usage of the electrical grid 424.

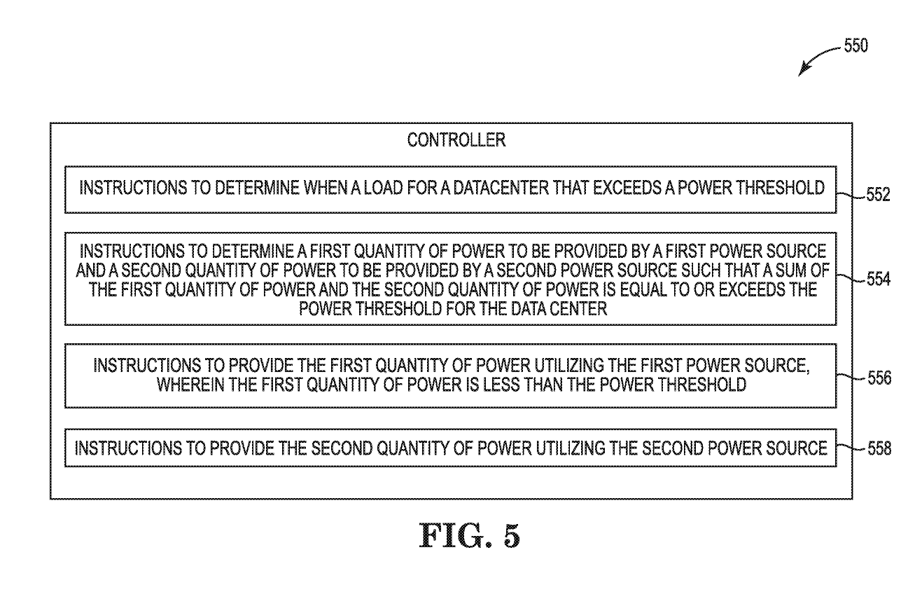

FIG. 5 illustrates an example controller 550 for data center fuel cells consistent with the present disclosure. In some examples, the controller 550 can be a computing device that can execute instructions 552, 554, 556, 558 to perform particular functions. For example, the controller 550 can include a memory resource to store instructions 552, 554, 556, 558 executable by a processing resource to manage power resources and computing resources for a data center.

In some examples, the controller 550 can include instructions 552 that are executable by a processing resource to determine when a load for a data center exceeds a power threshold. In some examples, the controller 550 can monitor a power usage for a data center. The data center can include a plurality of racks that each include a plurality of computing devices (e.g., servers, etc.). The data center can also include a plurality of devices to manage and maintain the plurality of racks. For example, the data center can include fans and liquid cooling devices to manage the temperature of the plurality of racks. Thus, the data center can utilize a particular quantity of electrical power to generate computing resources utilizing the plurality of racks. In some examples, load thresholds can be exceeded at the a server, rack, row, and/or data center levels. For example, determining the load for the data center can be accomplished using monitoring at the server level, rack level, row level, and/or overall data center levels.

In some examples, the controller 550 can determine when the load for the data center exceeds a particular threshold. In some examples, the threshold can be a quantity of electrical power to be extracted from the electrical grid. In some examples, the threshold can be a quantity of electrical power that exceeds a current level of power that can be extracted from the electrical grid. In other examples, the threshold can be a quantity of power that is within a particular price structure of a power company providing the electrical grid. Thus, the controller 550 can determine when the power usage of the data center will exceed a particular level.

In some examples, the controller 550 can include instructions 554 that are executable by a processing resource to determine a first quantity of power to be provided by a first power source and a second quantity of power to be provided by a second power source such that a sum of the first quantity of power and the second quantity of power is equal to or exceeds the power threshold for the data center. In some examples, the threshold can be a threshold for a first power source, such as the electrical grid. As described herein, the electrical grid may be capable of providing a particular quantity of electrical power to the data center. Thus, the threshold for the first power source can be a maximum quantity of power that the first power source is capable of providing.

In some examples, the first quantity of power to be provided by the first power source can be a particular quantity of power to be extracted from the electrical grid. As described herein, the controller 550 can utilize a number of different thresholds for the electrical grid and the controller 550 can base the first quantity of power to be extracted from the electrical grid on the number of different thresholds for the electrical grid. For example, the first quantity of power to be extracted from the electrical grid can be a maximum quantity of power that the electrical grid is capable of providing to the data center. In this example, the second quantity of power provided by the second power source can be a quantity of power utilized by the data center that exceeds the threshold. In some examples, the second power source can be a fuel cell as described herein. In these examples, the fuel cell can provide power in parallel with the electrical grid to provide electrical power to the data center in excess of the threshold.

In some examples, the controller 550 can include instructions 556 that are executable by a processing resource to provide the first quantity of power utilizing the first power source, wherein the first quantity of power is less than the power threshold. As described herein, providing the first quantity of power can include the controller 550 utilizing a switching mechanism to allow the first quantity of power to be provided to the data center. In some examples, the switching mechanism can provide power in parallel from the first power source and the second power source such that the first power source can provide the first quantity of power and the second power source can provide the second quantity of power. As described herein, the first quantity of power can be less than the power threshold and the second quantity of power can be provided in parallel such that the data center can utilize a total quantity of power that exceeds the power threshold.

In some examples, the controller 550 an include instructions to alter a state of the second power source based on a power demand of the data center. For example, the controller 550 can be utilized to activate the fuel cell when the power demand for the data center exceeds a particular threshold. In some examples, the fuel cell can be activated by the controller 550 to provide power in parallel with the electrical grid as described herein. In some examples, the controller 550 can include instructions to alter a state of the second power source based on load shedding incentives from the electric utility company. As described further herein, a power company can provide monetary incentives to organizations that lower power consumption. In this way, the controller 550 can activate the fuel cell to provide supplemental power when the controller 550 lowers the power extracted from the electrical grid.

In some examples, the controller 550 can include instructions to determine a time period to alter a power distribution percentage between the first power source and the second power source. In some examples, the determined time period can be a time period when an expected spike is about to occur. For example, the time period can correspond to when auctions end for an auction web service. In this example, the controller 550 can activate the fuel cell and alter the power distribution percentage during the expected spike such that the electrical grid does not have to provide the added resources to provide the additional power to the data center for non-spike periods.

In some examples, the controller 550 can include instructions 558 that are executable by a processing resource to provide the second quantity of power utilizing the second power source. As described herein, the controller 550 can utilize a switching mechanism to provide the second quantity of power utilizing the second power source. In some examples, the controller 550 can include instructions to lower power provided by the first power source by a particular quantity of power and increase power provided by the second power source by the particular quantity of power. In some examples, the controller 550 can alter the quantity of power provided by the first power source and the second power source utilizing a switching mechanism.

As described herein, the switching mechanism can be utilized to provide power from the first power source and the second power source in parallel to allow the total power utilized by the data center to exceed the power threshold. In some examples, the data center can exceed the power threshold without suffering the consequences of exceeding the power threshold. For example, exceeding the power threshold can result in a power failure for the data center, extra cost to an owner of the data center, among other consequences. In this example, providing power to the data center from the first power source that is below the power threshold and providing power to the data center from the second power source that in sum exceeds the power threshold can allow the data center to exceed the power threshold without resulting in a power failure or extra cost to the owner.

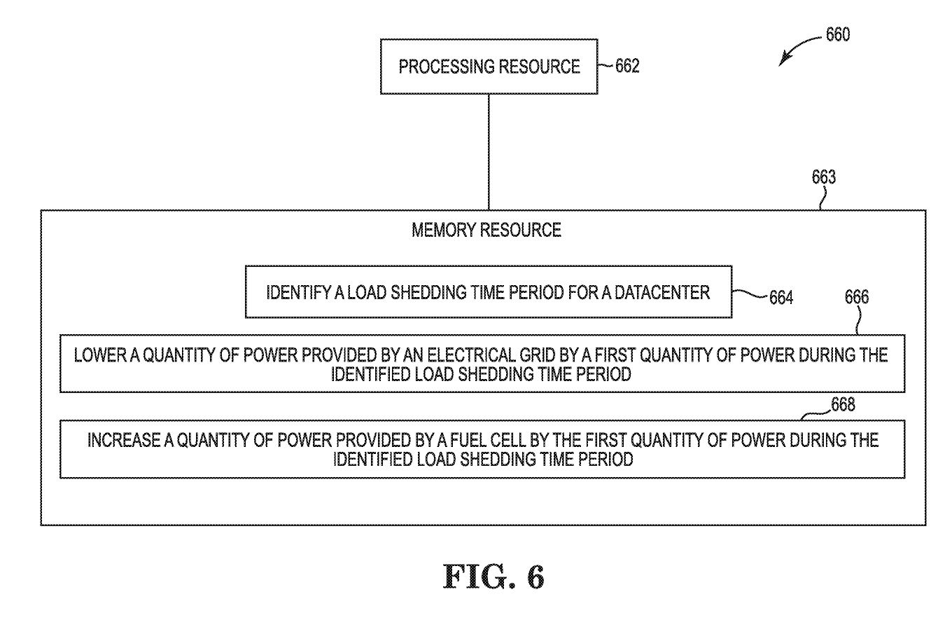

FIG. 6 illustrates an example computing device 660 for data center fuel cells consistent with the present disclosure. In some examples, the computing device 660 can execute instructions 664, 666, 668 to perform particular functions. For example, the computing device 660 can include a memory resource 663 to store instructions 664, 666, 668 executable by a processing resource 662 to manage power resources and computing resources for a data center. In some examples, the memory resource 663 can be utilized to store instructions 664, 666, 668 that can be executed by a processing resource 662 to perform functions described herein. In some examples, the processing resource 662 can be coupled to the memory resource 663 via a connection. A processing resource 662 may be a central processing unit (CPU), microprocessor, and/or other hardware device suitable for retrieval and execution of instructions stored in memory resource 663.

Memory resource 663 may be any electronic, magnetic, optical, or other physical storage device that stores executable instructions 664, 666, 668. Thus, memory resource 663 may be, for example, Random Access Memory (RAM), an Electrically-Erasable Programmable Read-Only Memory (EEPROM), a storage drive, an optical disc, and the like. The executable instructions 664, 666, 668 may be stored on the memory resource 663. Memory resource 663 may be a portable, external or remote storage medium, for example, that allows the instructions 664, 666, 668 to be downloaded from the portable/external/remote storage medium. In this situation, the executable instructions 664, 666, 668 may be part of an “installation package”. As described herein, memory resource 663 may be encoded with executable instructions 664, 666, 668 for managing power resources and computing resources of a data center as described herein.

In some examples, the memory resource 663 can include instructions 664 that are executable by a processing resource 662 to identify a load shedding time period for a data center. As used herein, a load shedding time period can be a quantity of time or particular date range where a utility company or power company can provide incentives to utilize power below a particular threshold. For example, when power usage for an area is expected to be relatively high, a utility company can offer incentives to organizations that lower their power consumption.

In this example, the data center can utilize the load shedding time period to receive the incentives from the utility company while still utilizing a normal level of power by utilizing power from the electrical grid in parallel with utilizing power from a fuel cell. In this way, the data center can receive the incentives without sacrificing performance of the computing devices. That is, the computing devices utilize a relatively higher performance during the load shedding time and also receive the incentives for complying with the lowered power consumption from the electrical grid.

In some examples, the memory resource 663 can include instructions 666 that are executable by a processing resource 662 to lower a quantity of power provided by an electrical grid by a first quantity of power during the identified load shedding time period. As described herein, the load shedding time period can be a period of time when the data center can lower power consumption from the electrical grid to receive incentives from a utility company. Thus, the computing device 660 can alter a switching mechanism to lower a quantity of power extracted from the electrical grid to a level that will qualify for the load shedding time period. In some examples, the memory resource 663 can include instructions to increase the quantity of power extracted from the electrical grid by the first quantity of power when the load shedding time period has ended. In some examples, the memory resource 663 can include instructions to deactivate the fuel cell when the load shedding time period has ended.

In some examples, the devices of the data center remain in a particular state during the load shedding time period. In some examples, the particular state can be a normal operation state, which can be utilized during normal operation of the data center. For example, the devices of the data center can include computing resources and/or cooling resources. In this example, the computing resources may not be altered to a different power state or performance state to save or conserve electrical power. That is, power capping may not be utilized for the devices during the load shedding time period. In some examples, the particular state is a state that does not include a power cap for the devices of the data center. As used herein, power capping can, for example, include limiting a peak power consumption of a computing device, a server chassis, and/or a data center.

In some examples, the memory resource 663 can include instructions 668 that are executable by a processing resource 662 to increase a quantity of power provided by a fuel cell by the first quantity of power during the identified load shedding time period. In some examples, the memory resource 663 can include instructions to increase the quantity of power provided by a fuel cell in response to a determination that the data center is approaching a maximum power consumption level. In some examples, the maximum power consumption level for the data center can be a maximum power consumption level that can be extracted from the electrical grid. For example, the data center can include electrical devices to convert the power from the electrical grid to be utilized by the data center. In this example, the electrical grid can be capped or have a maximum quantity of power that can be provided to the data center based on the capabilities of the electrical devices.

As described herein, the computing device 660 can utilize a switching mechanism to provide electrical power from the electrical grid and the fuel cell in parallel to provide power to the data center that exceeds the threshold of the load shedding time period and allows the data center to qualify for the incentives of the load shedding time period. In some examples, the computing device 660 can increase the quantity of power provided by the fuel cell by the same or similar quantity as the computing device 660 lowered the power extracted from the electrical grid. In this way, the data center can utilize the same or similar quantity of power and also qualify for the incentives of the load shedding time period.

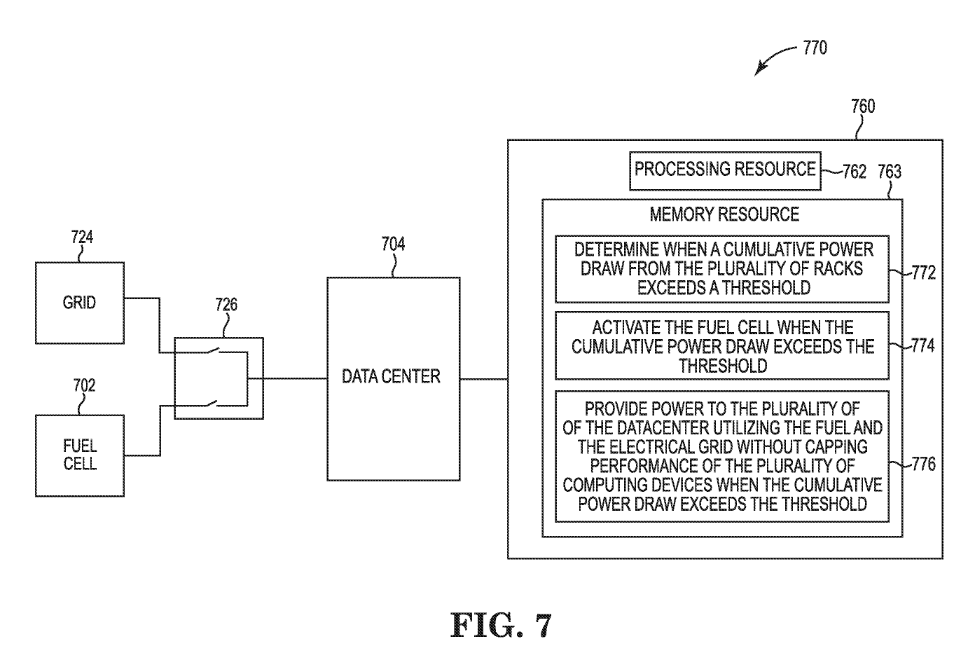

FIG. 7 illustrates an example system 770 for data center fuel cells consistent with the present disclosure. In some examples, the system 770 can include the same or similar elements as system 100 as referenced in FIG. 1, system 220 as referenced in FIG. 2, system 330 as referenced in FIG. 3, and/or system 440 as referenced in FIG. 4. In some examples, the system 770 can include a data center 704 that includes a plurality of racks that include a corresponding plurality of computing devices. For example, the data center 704 can include a plurality of batteries (e.g., battery 112 as referenced in FIG. 1, etc.), and/or a plurality of servers (e.g., server 108 and server 110 as referenced in FIG. 1, etc.).

In some examples, the system 770 can include a direct current to alternating current (DC/AC) inverter to receive DC power from the fuel cell 702 and provide AC power to the second power input of the switching mechanism 726. In some examples, the system 770 can include an electrolysis device coupled to the fuel cell 702 to provide hydrogen to the fuel cell 702. In other examples, the system 770 can include a natural gas reformer coupled to the fuel cell 702 to provide hydrogen to the fuel cell 702.

In some examples, the system 770 can include a first power input of the data center 704 coupled to an electrical grid 724. In some examples, the first power input of the data center 704 can be a first input of a switching mechanism 726. In some examples, the system 770 can include a second power input of the data center coupled to a fuel cell 702. In some examples, the second power input of the data center 704 can be a second input of the switching mechanism 726. As described herein, the switching mechanism 726 can be utilized to provide power from the electrical grid 724 and the fuel cell 702 in parallel and at specific percentages or particular quantities of power.

In some examples, the system 770 can include a computing device 760 that can be coupled to the data center 704. In some examples, the computing device 760 can be utilized to control the switching mechanism 726 to control the power management of the data center 704 and also to control or manage computing resources (e.g., servers, cooling resources, etc.) of the data center 704. In some examples, the computing device 760 can execute instructions 772, 774, 776 to perform particular functions. For example, the computing device 760 can include a memory resource 763 to store instructions 772, 774, 776 executable by a processing resource 762 to manage power resources and computing resources for a data center 704. In some examples, the memory resource 763 can be utilized to store instructions 772, 774, 776 that can be executed by a processing resource 762 to perform functions described herein.

In some examples, the memory resource 763 can include instructions 772 that are executable by a processing resource 762 to determine when a cumulative power draw from the plurality of racks exceeds a threshold. In some examples, the data center 704 can include a plurality of racks that can each include a plurality of computing resources (e.g., servers, server blades, etc.). In some examples, the cumulative power draw from the plurality of racks can be a power usage of the computing resources of the data center 704. In some examples, each of the plurality of racks can include a particular power threshold and the computing device 760 can monitor the power usage of each of the plurality of racks as well as the cumulative power draw for the data center 704.

In some examples, the memory resource 763 can include instructions 774 that are executable by a processing resource 762 to activate the fuel cell 702 when the cumulative power draw exceeds the threshold. In some examples, the fuel cell 702 can be a fast ramp fuel cell that can utilize a relatively shorter ramp up period. As used herein, a ramp up period can be a quantity of time it takes a device to be operational or usable for resources. In these examples, the fuel cell 702 can be activated when the cumulative power draw exceeds the threshold to provide additional power to the data center 704 to allow the data center 704 to operate above the threshold.

In some examples, the memory resource 763 can include instructions 776 that are executable by a processing resource 762 to provide power to the plurality of racks of the data center utilizing the fuel cell and the electrical grid without capping performance of the plurality of computing devices when the cumulative power draw exceeds the threshold. In some examples, capping performance of the plurality of computing devices includes lowering a performance of the plurality of computing devices to conserve electrical power.

As described herein, the switching mechanism 726 can be utilized by the computing device 760 to provide power from the electrical grid 724 and the fuel cell 702 in parallel. When the fuel cell 702 is activated to provide additional power through the switching mechanism 726, the data center 704 can operate with power that exceeds the threshold and the performance of the plurality of computing devices (e.g., servers, etc.) does not have to be capped or altered to decrease the power consumption of the data center 704. Previous systems would alter or decrease the performance of the computing devices to lower the power consumption of the data center 704 to a level below the threshold. In some examples, performance capping of the computing resources can be prevented by utilizing the switching mechanism 726 and the fuel cell 702.

In the foregoing detailed description of the present disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the present disclosure.

The figures herein follow a numbering convention in which the first digit corresponds to the drawing figure number and the remaining digits identify an element or component in the drawing. Elements shown in the various figures herein can be added, exchanged, and/or eliminated so as to provide a number of additional examples of the present disclosure. In addition, the proportion and the relative scale of the elements provided in the figures are intended to illustrate the examples of the present disclosure and should not be taken in a limiting sense. As used herein, the designator “N”, particularly with respect to reference numerals in the drawings, indicates that a number of the particular feature so designated can be included with examples of the present disclosure. The designators can represent the same or different numbers of the particular features. Further, as used herein, “a number of” an element and/or feature can refer to one or more of such elements and/or features.

What is claimed:

1. A controller, comprising instructions to:
determine when a load for a data center exceeds a power threshold;
determine a first quantity of power to be provided by a first power source and a second quantity of power to be provided by a second power source such that a sum of the first quantity of power and the second quantity of power is equal to or exceeds the power threshold for the data center;
provide the first quantity of power utilizing the first power source, wherein the first quantity of power is less than the power threshold; and
provide the second quantity of power utilizing the second power source.

2. The controller of claim 1, wherein the first power source is a grid power source that is capable of providing electrical power up to the power threshold.

3. The controller of claim 1, wherein the second power source is a fuel cell.

4. The controller of claim 1, comprising instructions to:
lower power provided by the first power source by a particular quantity of power; and
increase power provided by the second power source by the particular quantity of power.

5. The controller of claim 1, comprising instructions to alter a state of the second power source based on a power demand of the data center.

6. The system of claim 1, comprising instructions to alter a state of the second power source based on load shedding incentives.

7. The system of claim 1, comprising instructions to determine a time period to alter a power distribution percentage between the first power source and the second power source.

8. A non-transitory machine-readable storage medium having stored thereon machine-readable instructions to cause a computer processor to:
identify a load shedding time period for a data center;
lower a quantity of power provided by an electrical grid by a first quantity of power during the identified load shedding time period; and
increase a quantity of power provided by a fuel cell by the first quantity of power during the identified load shedding time period.

9. The medium of claim 8, comprising instructions to activate the fuel cell at a particular time based on the identified load shedding time period.

10. The medium of claim 8, comprising instructions to increase the quantity of power extracted from the electrical grid by the first quantity of power when the load shedding time period has ended.

11. The medium of claim 8, comprising instructions to deactivate the fuel cell when the load shedding time period has ended.

12. The medium of claim 8, wherein devices of the data center remain in a normal operation state during the load shedding time period.

13. The medium of claim 12, wherein the normal operation state is a state that does not include a power cap for the devices of the data center.

15. The medium of claim 8, comprising instructions to increase the quantity of power provided by the fuel cell in response to a determination that the data center is approaching a maximum power consumption level.

16. A system comprising:
a data center that includes a plurality of racks that include a corresponding plurality of computing devices;
a first power input of the data center coupled to an electrical grid;
a second power input of the data center coupled to a fuel cell; and
a computing device, comprising instructions to:
determine when a cumulative power draw from the plurality of racks exceeds a threshold;
activate the fuel cell when the cumulative power draw exceeds the threshold;
provide power to the plurality of racks of the data center utilizing the fuel cell and the electrical grid without capping performance of the plurality of computing devices when the cumulative power draw exceeds the threshold.

17. The system of claim 16, wherein capping performance of the plurality of computing devices includes lowering a performance of the plurality of computing devices to conserve electrical power.

18. The system of claim 16, comprising a direct current to alternating current (DC/AC) inverter to receive DC power from the fuel cell and provide AC power to the second power input.

19. The system of claim 16, comprising an electrolysis device coupled to the fuel cell to provide hydrogen to the fuel cell.

20. The system of claim 16, comprising a natural gas reformer coupled to the fuel cell to provide hydrogen to the fuel cell.
